(19) United States
(12) Patent Application Publication
(10) Pub. No.: US 2018/0255655 A1
(43) Pub. Date: Sep. 6, 2018

(54) ELECTRONIC DEVICE WITH PROTECTED CORNERS

(71) Applicant: MSI COMPUTER(SHENZHEN) CO., LTD., Shenzhen City (CN)

(72) Inventors: Fang-Yu LIN, New Taipei City (TW); Bin-An HSIEH, New Taipei City (TW)

(21) Appl. No.: 15/471,633

(22) Filed: Mar. 28, 2017

(30) Foreign Application Priority Data
Mar. 3, 2017 (TW) 106203013

(51) Int. Cl. H05K 5/02; H05K 5/00

(52) U.S. Cl. CPC H05K 5/0217; F16F 1/36; H05K 5/0008

(57) ABSTRACT

An electronic device with protected corners includes a main device body and a plurality of composite corner-pad structures. The main device body having an operation surface and an opposite back surface further includes a plurality of lateral sides, and two adjacent lateral sides are connected via a corner portion so as to make the main device body having a plurality of corner portions. Each the corner portion has a first corner-portion surface on the operation surface and a second corner-portion surface on the back surface. The plurality of composite corner-pad structures are individually and detachably mounted fixedly on the corresponding corner portions. Each of composite corner-pad structures includes a first corner pad and a second corner pad. The first corner pad covers at least part of the first corner-portion surface, and the second corner pad assembled to the first corner pad covers at least part of the second corner-portion surface.

This application claims the benefit of Taiwan Patent Application Serial No. 106203013, filed Mar. 3, 2017, the subject matter of which is incorporated herein by reference.

### BACKGROUND OF THE INVENTION

### 1. Field of the Invention

The invention relates to an electronic device, and more particularly to the electronic device with protected corners.

### 2. Description of the Prior Art

Generally speaking, since an electronic device usually consists of various precision electronic components, thus impacts upon the electronic device caused by accidental drops or collisions are usually vulnerable to damaging the internal electronic components, and so as further to dysfunction the electronic device.

Thanks to recent rapid developments in communication technology, smart electronic devices have provided more convenient and intrinsic manipulation to users. Hence, no matter where the operation environment is, in normal living or at work, the usage of smart electronic devices is significantly elevated.

As described above, in order to extend the service life of smart electronic device, some protective accessories have been introduced to the smart electronic device so as thereby to reduce possible damages caused by accidental drops or collisions.

Referring now to FIG. 1, a schematic plane view of a conventional smart electronic device with a protection accessory is shown. In the art, a corner portion PA11 of the conventional smart electronic device PA1 is protected by an anti-collision pad PA2 so as to prevent the smart electronic device PA1 from impacts. Although the resort of having the anti-collision pad PA2 to shield the corner portion PA11 of the smart electronic device PA1 can increase crashworthiness of the smart electronic device PA1, yet, for the current anti-collision pad PA2 can only be directly applied to the corner portion PA11 of the smart electronic device PA1, the protection upon the electronic device against impacts caused by unexpected peeling-off of the anti-collision pad PA2 is limited. In addition, in comparison with the back surface of the smart electronic device PA1 that provides better strength, the front glass-screen surface of the smart electronic device PA1 is much vulnerable to be damaged, and thus the anti-collision requirement at the front surface is much higher. However, since the current anti-collision pad PA2 is a unique-piece structure, thus different anti-collision ability would be provided to the front surface and the back surface of the smart electronic device PAL

Referring now to FIG. 2, a schematic separated plane view of another conventional smart electronic device with a protection accessory is shown. As illustrated, in the current art, a corner portion PA31 of a typical smart electronic device PA3 can be built with an interference structure. The anti-collision pad PA4 is bent to engage firmly with the corner portion PA31 of the smart electronic device PA3 by matching the interference structure of the corner portion PA31 and a corresponding slot of the anti-collision pad PA4. Though the anti-collision pad PA4 is elastic so as to provide enough collision resistance, yet, in order to mount the anti-collision pad PA4 to the corner portion PA31 through the interference structure PA311, fluctuating elastic deformations of the anti-collision pad PA4 caused by frequent bending would lead to propagation of cracks due to stress concentration. Thereupon, engagement tightness between the corner portion PA31 of the smart electronic device PA3 and the anti-collision pad PA4 would be a problem.

### SUMMARY OF THE INVENTION

In view of the current art, though specific anti-collision accessories are usually provided to protect the corner portion of smart electronic device, yet reliability of the anti-collision accessories is always a concern. Accordingly, it is an object of the present invention to provide an electronic device with protected corners so as to ensure the reliability of the anti-collision accessories. In addition, the problem of different anti-collision ability on opposing surfaces of the electronic device can be further resolved.

In the present invention, the electronic device with protected corners includes a main device body and a plurality of composite corner-pad structures.

The main device body has an operation surface and a back surface opposing to the operation surface, and further has a plurality of lateral sides, in which every two adjacent lateral sides are connected with a corner portion so that the main device body has a plurality of the corner portions. Each of the corner portions has a first corner-portion surface on the operation surface and a second corner-portion surface on the back surface. In addition, each of the corner portions further has at least one lateral screw hole, and the first corner-portion surface further has a bulge structure.

The plurality of composite corner-pad structures are mounted fixedly and detachably onto the plurality of corresponding corner portions. Each of the plurality of composite corner-pad structures includes a first corner pad and a second corner pad. The first corner pad is to shield at least part of the first corner-portion surface. The second corner pad is to shield at least part of the second corner-portion surface and to be assembled with the first corner pad. The first corner pad has at least one protruding portion and an aperture structure for matching the bulge structure. Each of the plurality of corner portions further has at least one lateral screw hole, the first corner pad has at least one protruding portion, the at least one protruding portion is constructed with a first mounting hole in correspondence with the at least one lateral screw hole, the second corner pad has at least one fixation portion in correspondence with the at least one protruding portion, and the at least one fixation portion is constructed with a second mounting hole in correspondence with the at least one lateral screw hole. Thereupon, the second mounting hole and the first mounting hole are overlapped by matching the at least one protruding portion and the at least one fixation portion and further screwed fixedly via the at least one lateral screw hole.

In one embodiment of the present invention, the electronic device with protected corners further includes a side frame connected between two adjacent said composite corner-pad structures. The side frame is detachably assembled to connect the two adjacent composite corner-pad structures. Preferably, the side frame is integrated as a unique piece with the two adjacent composite corner-pad structures. In addition, the side frame further includes a first side frame and a second side frame. The first side frame is integrated as a unique piece with the two adjacent first corner pads of the composite corner-pad structure. The second side frame is integrated as a unique piece with the two adjacent second corner pads of the composite corner-pad structure, and connected with the corresponding first side frame.

As described above, the electronic device with protected corners of the present invention applies the composite corner-pad structure to protect the corner portion of the main device body in a detachable manner, in which the composite corner-pad structure is consisted of the first corner pad and the second corner pad screwed fixedly to the first corner pad. Thereupon, the first corner pad and the second corner pad can be easily to vary the pairing pattern thereof accordingly to meet various shapes, interference structures or bulge structures of the first corner-portion surface and the second corner-portion surface, and so as further to enhance the engagement stability of the composite corner-pad structure on the corner portion. Also, since the first corner pad and the second corner pad are separate elements, thus the user can be free to choose the materials for producing individually the first corner pad and the second corner pad in accordance with specific anti-collision requirements of the first corner-portion surface and the second corner-portion surface.

All these objects are achieved by the electronic device with protected corners described below.

### BRIEF DESCRIPTION OF THE DRAWINGS

The present invention will now be specified with reference to its preferred embodiment illustrated in the drawings, in which:

FIG. 1 is a schematic plane view of a conventional smart electronic device with a protection accessory;

FIG. 2 is a schematic separated plane view of another conventional smart electronic device with a protection accessory;

FIG. 3 is a schematic perspective view of a first embodiment of the electronic device with protected corners in accordance with the present invention;

FIG. 4 is a schematic cross-sectional view of FIG. 3 along line A-A;

FIG. 5 is a schematic exploded view of a portion of FIG. 4;

FIG. 6 is a schematic exploded view of a portion of FIG. 3;

FIG. 7 is another view of FIG. 6;

FIG. 8 is a schematic plane view of a second embodiment of the electronic device with protected corners in accordance with the present invention, with two of four corner pads separated;

FIG. 9 is a schematic perspective view of a third embodiment of the electronic device with protected corners in accordance with the present invention; and

FIG. 10 is a schematic rear view of FIG. 9.

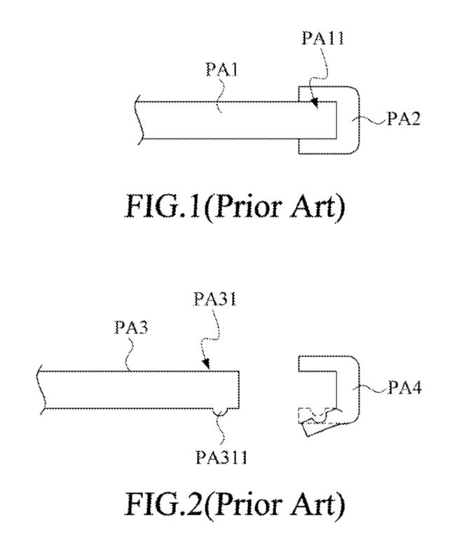

### DESCRIPTION OF THE PREFERRED EMBODIMENT

The invention disclosed herein is directed to an electronic device with protected corners. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

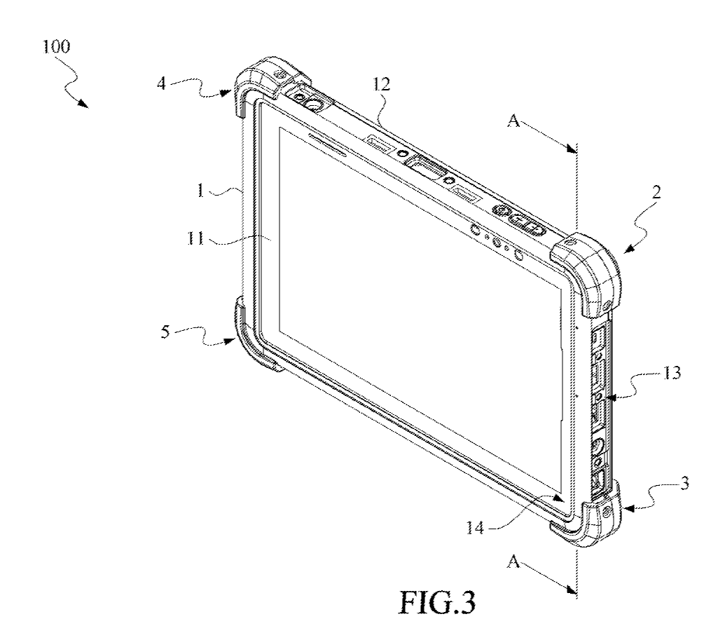

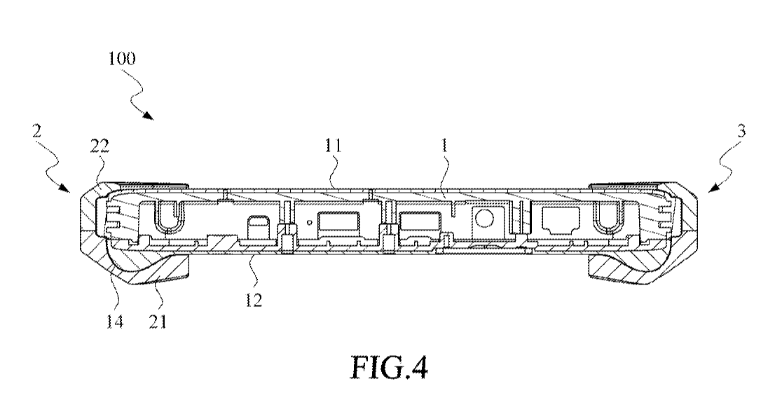

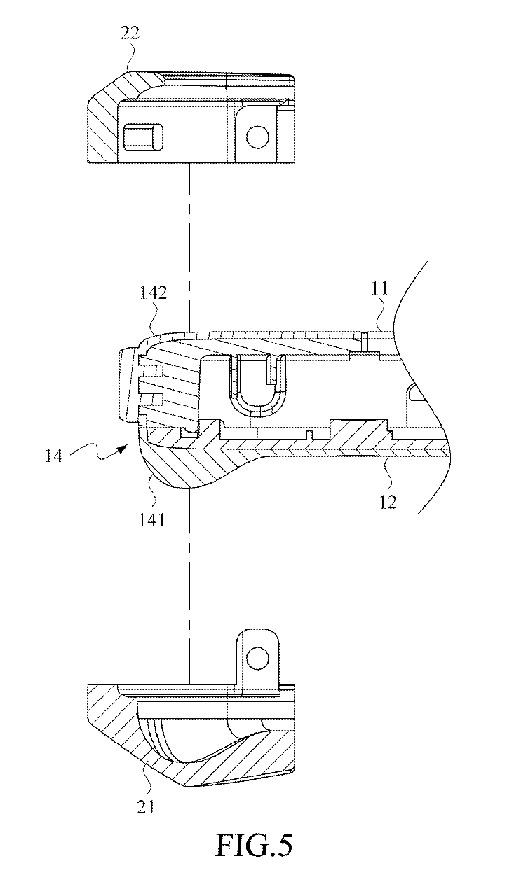

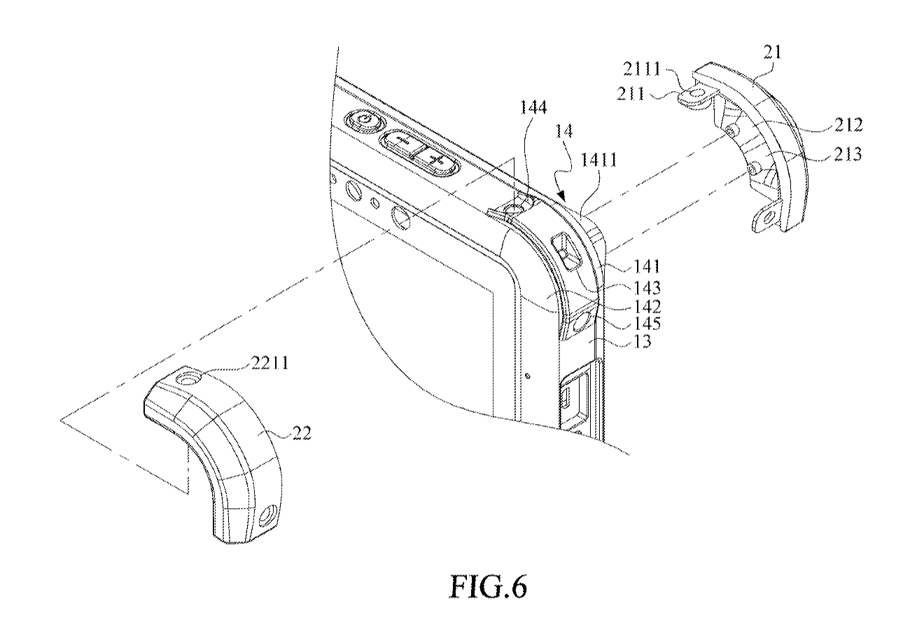

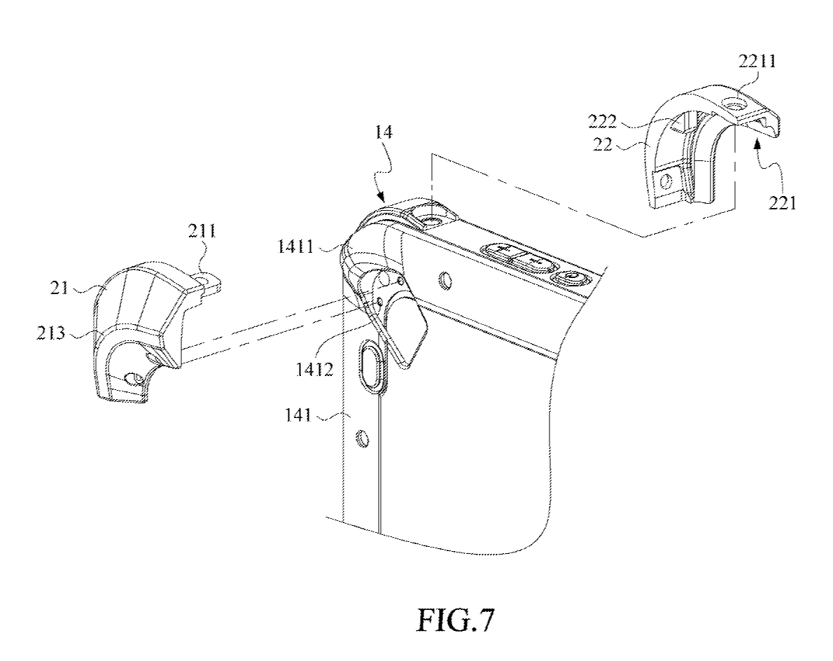

Refer now to FIG. 3 through FIG. 7; where FIG. 3 is a schematic perspective view of a first embodiment of the electronic device with protected corners in accordance with the present invention, FIG. 4 is a schematic cross-sectional view of FIG. 3 along line A-A, FIG. 5 is a schematic exploded view of a portion of FIG. 4, FIG. 6 is a schematic exploded view of a portion of FIG. 3, and FIG. 7 is another view of FIG. 6.

As shown, the electronic device with protected corners 100 includes a main device body 1 and four composite corner-pad structures 2, 3, 4 and 5.

The main device body 1 has an operation surface 11 (the front surface) and a back surface 12 opposite to the operation surface 11, and also includes four lateral sides 13 (only one labeled in the figure). Every two adjacent lateral sides 13 are connected by a corner portion 14 so as to allow the main device body 1 to have four said corner portions 14 (only one labeled in the figure). Each of the corner portions 14 includes a first corner-portion surface 141 (only one labeled in the figure) on the operation surface 11 and a second corner-portion surface 142 (only one labeled in the figure) on the back surface 12. Further, the first corner-portion surface 141 has a bulge structure 1411 and two lateral positioning screw holes 1412 (as shown in FIG. 7 with only one labeled). In addition, each of the corner portions 14 further includes an aperture structure 143 and two lateral screw holes 144 and 145 located individually to two opposing sides of the aperture structure 143.

The plurality of composite corner-pad structures 2, 3, 4 and 5 are individually mounted onto four corresponding corner portions 14 in a detachable manner. By having the composite corner-pad structure 2 as a typical example, the composite corner-pad structure 2 includes a first corner pad 21 and a second corner pad 22.

The first corner pad 21 for partly shielding the first corner-portion surface 141 has two protruding portions 211 (only one labeled in the figure), two position pillars 212 and an aperture structure 213.

Each of the two protruding portions 211 is constructed with a first mounting hole 2111 (only one labeled in the figure) respective to the corresponding lateral screw hole 144. The two position pillars 212 are individually located to account for the two corresponding lateral positioning screw holes 1412, such that the first corner pad 21 can temporarily anchor on the first corner-portion surface 141 via the mating of the two position pillars 212 and the two corresponding lateral positioning screw holes 1412. Thereafter, a screw or screws can be applies to fix the first corner pad 21 firmly on the first corner-portion surface 141. The aperture structure 213 is positioned in correspondence with the bulge structure 1411, so that, as the first corner pad 21 is fixed into the first corner-portion surface 141, the bulge structure 1411 can be shielded as well.

The second corner pad 22 has two fixation portions 221 (only one labeled in the figure) respective to the two corresponding protruding portions 211 and a positioning structure 222. Each of the two fixation portions 221 is constructed with a second mounting hole 2211 (only one labeled in the figure) respective to the corresponding lateral screw hole 144, so that the second mounting hole 2211 and the corresponding first mounting hole 2111 can be overlapped via the matching of the protruding portion 211 and the corresponding fixation portion 221 so as further to allow the first corner pad 21 and the second corner pad 22 together able to be mounted fixedly onto the corner portion 14 by screwing, The positioning structure 222 is positioned in correspondence with the aperture structure 143, so that, as the second corner pad 22 covers the corresponding second corner-portion surface 142, the engagement stability of the second corner pad 22 and the first corner pad 21 on the corner portion 14 can be enhanced by matching the positioning structure 222 and the corresponding aperture structure 143.

As described above, the electronic device with protected corners 100 of the present invention applies four composite corner-pad structures 2, 3, 4 and 5 to protect the four corresponding corner portions 14 of the main device body 1 by shielding, the corner-pad structure 2 is divided into the first corner pad 21 and the second corner pad 22 for covering the first corner-portion surface 141 and the second corner-portion surface 142, respectively prior to the engagement in between, and thus users can select proper materials for producing the first corner pad 21 and the second corner pad 22, respectively in accordance with different anti-collision requirements of the first corner-portion surface 141 and the second corner-portion surface 142. For example, a shock-absorbing material can be used to produce the second corner pad 22 because the first corner-portion surface 141 to be shielded is a portion of the operation surface 11, and a stiffer abrasive material can be chosen to produce the first corner pad 21 because the second corner-portion surface 142 to be shielded is a part of the device housing.

In addition, the first corner pad 21 and the second corner pad 22 can individually shield the first corner-portion surface 141 and the second corner-portion surface 142, respectively, prior to the assembling. Since the first corner-portion surface 141 has the bulge structure 1411 to be completely covered by the first corner pad 21, thus the engagement stability of the composite corner-pad structure 2 on the corresponding corner portion 14 can be substantially enhanced.

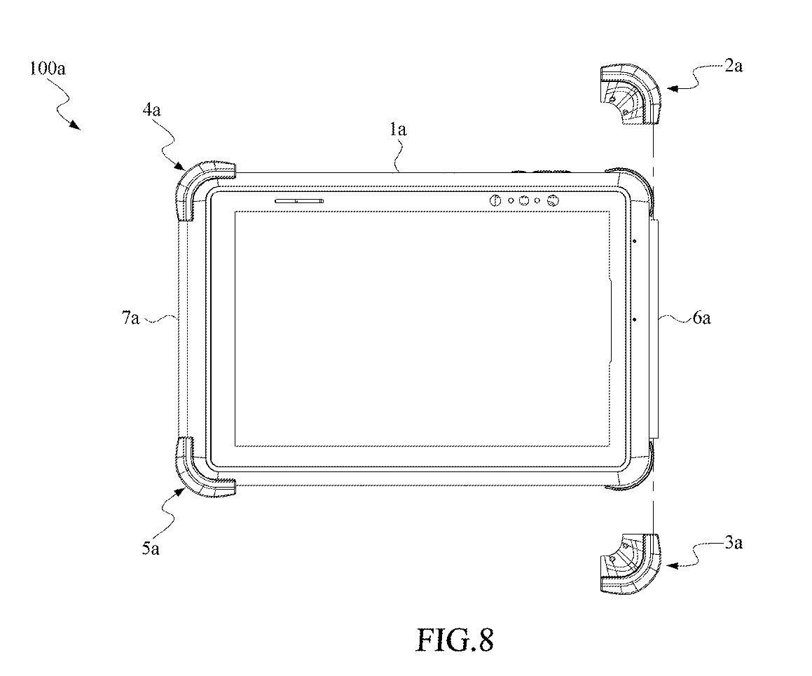

Referring now to FIG. 8, a schematic plane view of a second embodiment of the electronic device with protected corners in accordance with the present invention, with two of four corner pads separated, IS illustrated. As shown, similar structurally to the foregoing first embodiment, the electronic device with protected corners 100a of this embodiment includes the main device body 1a, the four composite corner-pad structures 2a, 3a, 4a and 5a, and two new side frames 6a and 7a.

The two side frames 6a and 7a are individually and detachably assembled to opposing sides of the main device body 1a. While two said composite corner-pad structures 2a and 3a are mounted fixedly onto two corresponding corner portions (not labeled in the figure, but at the position 14 in the previous embodiment) of the main device body 1a, these two composite corner-pad structures 2a and 3a can be individually connected fixedly with the side frame 6a. Similarly, while the two composite corner-pad structures 4a and 5a are mounted fixedly onto the corresponding corner portion of the main device body 1a, the two composite corner-pad structures 4a and 5a can be individually connected fixedly with the side frame 7a. Thereupon, the electronic device with protected corners 100a provided by this embodiment can further increase the engagement stability of the electronic device with protected corners 100 by introducing the composite corner-pad structures 2a, 3a, 4a and 5a, and the two side frames 6a and 7a.

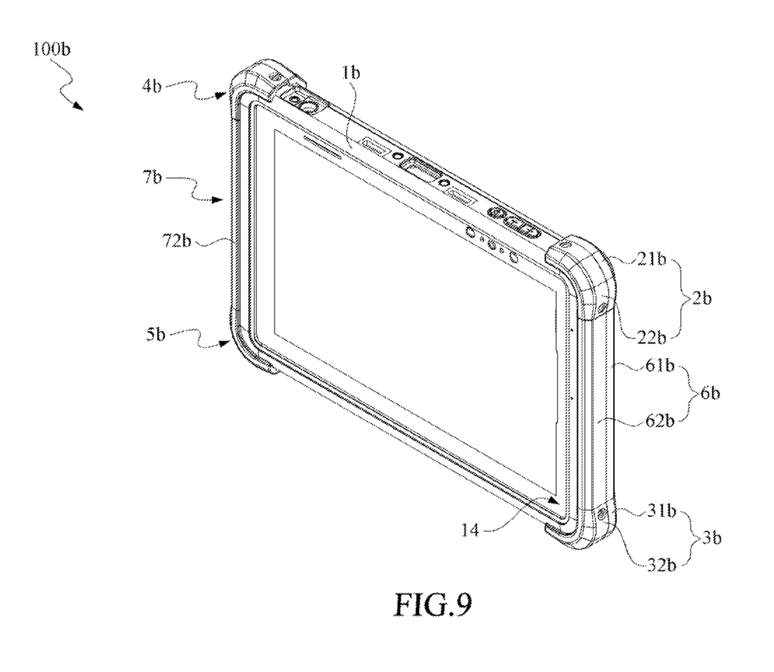

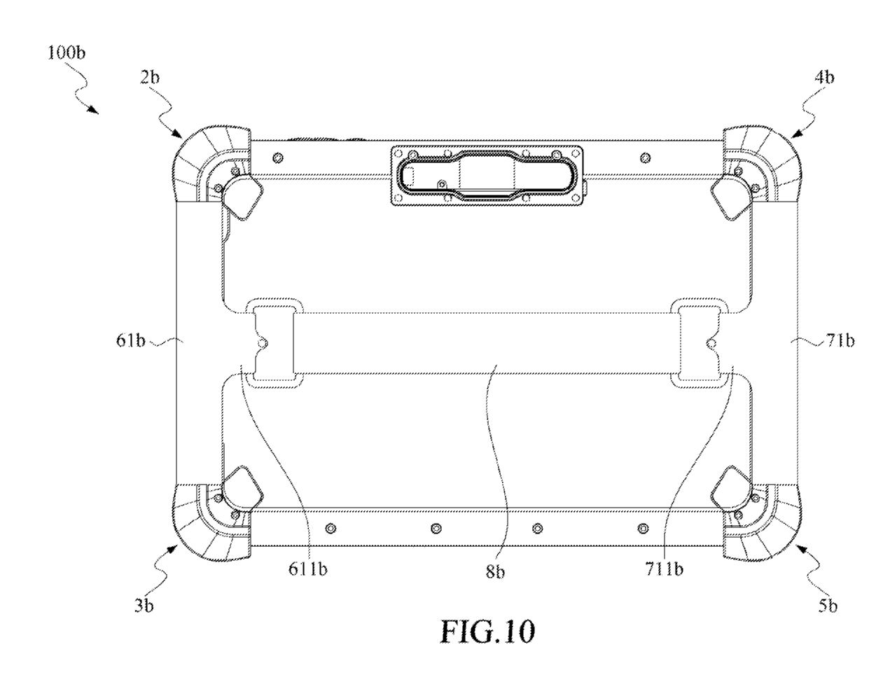

Refer now to FIG. 9 and FIG. 10; where FIG. 9 is a schematic perspective view of a third embodiment of the electronic device with protected corners in accordance with the present invention, and FIG. 10 is a schematic rear view of FIG. 9. As shown, similar structually to the foregoing second embodiment 100a, the electronic device with protected corners 100b provided by this embodiment includes a similar main device body 1b, the four composite corner-pad structures 2b, 3b, 4b and 5b, and the two side frames 6b and 7b. The major difference in between is that, in this embodiment, the side frame 6b further includes a first side frame 61b and a second side frame 62b. The first side frame 61b is integrated as a unique piece with the first corner pad 21 of the composite corner-pad structure 2b and the first corner pad 31b of the composite corner-pad structure 3b, while the second side frame 62b is integrated as a unique piece with the second corner pad 22b of the composite corner-pad structure 2b and the second corner pad 32b of the composite corner-pad structure 3b. Thereupon, the side frame 6b can be further fixed firmly to the lateral side of the electronic device with protected corners 100b. Similarly, a first side frame 71b and a second side frame 72b of the side frame 7b can be individually integrated with the composite corner-pad structures 4b and 5b.

In addition, in this embodiment, the first side frame 61b further has a connection portion 611b, the first side frame 71b further has a connection portion 711b corresponding to the connection portion 611b, and the electronic device with protected corners 100b further includes a connection-strip assembly 8b connected to the connection portions 611b and 711b individually so as to be constructed on the back surface of the electronic device with protected corners 100b. Thereupon, while the user operates the electronic device with protected corners 100b, the connection-strip assembly 8b can enhance the operation stability of the handheld electronic device with protected corners 100b.

In summary, in the conventional electronic device having the unique-piece U-shape protection accessories to clamp the corner portions thereof, the protection accessories cannot effectively hold the corresponding corner portions of the electronic device. Even that the interference structure is applied to increase the engagement stability of the protection accessories, the difficult-to-assemble and damage-in-assembly problems are still remained. On the other hand, the electronic device with protected corners of the present invention applies the composite corner-pad structure to protect the corner portion of the main device body in a detachable manner, in which the composite corner-pad structure is consisted of the first corner pad and the second corner pad screwed fixedly to the first corner pad. Thereupon, the first corner pad and the second corner pad can be easily to vary the pairing pattern thereof accordingly to meet various shapes, interference structures or bulge structures of the first corner-portion surface and the second corner-portion surface, and so as further to enhance the engagement stability of the composite corner-pad structure on the corner portion. Also, since the first corner pad and the second corner pad are separate elements, thus the user can be free to choose the materials for producing individually the first corner pad and the second corner pad in accordance with specific anti-collision requirements of the first corner-portion surface and the second corner-portion surface.

In addition, in the case that any of the first corner pad and the second corner pad is severely worn to be replaced, then replacement can be carried out only at the damaged pad, not at the entire composite corner-pad structure. Hence, relative expense for those replacements can be substantially reduced.

While the present invention has been particularly shown and described with reference to a preferred embodiment, it will be understood by those skilled in the art that various changes in form and detail may be without departing from the spirit and scope of the present invention.

1. An electronic device with protected corners, comprising:
a main device body, having an operation surface and a back surface opposing to the operation surface, further having a plurality of lateral sides, every two adjacent said lateral sides being connected with a corner portion so that the main device body has a plurality of the corner portions, each said corner portion having a first corner-portion surface on the operation surface and a second corner-portion surface on the back surface; and
a plurality of composite corner-pad structures, mounted fixedly and detachably onto the plurality of corresponding corner portions, each of the plurality of composite corner-pad structures including:
a first corner pad, shielding at least part of the first corner-portion surface; and
a second corner pad, shielding at least part of the second corner-portion surface and assembled with the first corner pad;
wherein the each of the plurality of corner portions further has at least one lateral screw hole, the first corner pad has at least one protruding portion, the at least one protruding portion is constructed with a first mounting hole in correspondence with the at least one lateral screw hole, the second corner pad has at least one fixation portion in correspondence with the at least one protruding portion, and the at least one fixation portion is constructed with a second mounting hole in correspondence with the at least one lateral screw hole; such that the second mounting hole and the first mounting hole are overlapped by matching the at least one protruding portion and the at least one fixation portion and further screwed fixedly via the at least one lateral screw hole.

2. (canceled)

3. The electronic device with protected corners of claim 1, wherein the first corner-portion surface further has a bulge structure and the first corner pad further has an aperture structure for matching the bulge structure.

4. The electronic device with protected corners of claim 1, further including a side frame connected between two adjacent said composite corner-pad structures.

5. The electronic device with protected corners of claim 4, wherein the side frame is detachably assembled to connect the two adjacent composite corner-pad structures.

6. The electronic device with protected corners of claim 4, wherein the side frame is integrated as a unique piece with the two adjacent composite corner-pad structures.

7. The electronic device with protected corners of claim 6, wherein the side frame further includes a first side frame and a second side frame, the first side frame is integrated as a unique piece with the first corner pads of the two adjacent composite corner-pad structures, and the second side frame connecting the first side frame is integrated as a unique piece with the second corner pads of the two adjacent composite corner-pad structure.
